(19) United States
(12) Patent Application Publication
(10) Pub. No.: US 2026/0052628 A1
(43) Pub. Date: Feb. 19, 2026

(54) STRETCHABLE DEVICE

(71) Applicant: Murata Manufacturing Co., Ltd., Nagaokakyo-shi (JP)

(72) Inventors: Koji YOSHIDA, Nagaokakyo-shi (JP); Ryo Asai, Nagaokakyo-shi (JP); Hayato Katsu, Nagaokakyo-shi (JP)

(21) Appl. No.: 19/371,039

(22) Filed: Oct. 28, 2025

Related U.S. Application Data
(63) Continuation of application No. PCT/JP2024/019140, filed on May 24, 2024.

(30) Foreign Application Priority Data
May 31, 2023 (JP) 2023-090216

(51) Int. Cl. H05K 1/11; H05K 1/02

(52) U.S. Cl. CPC H05K 1/115; H05K 1/0283

(57) ABSTRACT

A stretchable device that includes: a stretchable substrate; a first stretchable wiring on the stretchable substrate and having a first electrode portion; a second stretchable wiring on the first stretchable wiring and having a second electrode portion; and an interlayer sheet between the first stretchable wiring and the second stretchable wiring, in which the interlayer sheet includes a sheet portion and at least one first via portion in the sheet portion, and the first via portion has in a part thereof a connection region connecting the first electrode portion and the second electrode portion.

### CROSS REFERENCE TO RELATED APPLICATIONS

The present application is a continuation of International application No. PCT/JP2024/019140, filed May 24, 2024, which claims priority to Japanese Patent Application No. 2023-090216, filed May 31, 2023, the entire contents of each of which are incorporated herein by reference.

### TECHNICAL FIELD

The present disclosure relates to a stretchable device.

### BACKGROUND ART

Conventionally, a stretchable device including a stretchable substrate, a first stretchable wiring arranged on the stretchable substrate, and a second stretchable wiring arranged on the first stretchable wiring and connected through a via is known.
Patent Document 1: Japanese Patent Application Laid-Open No. 2021-77579

### SUMMARY OF THE DISCLOSURE

In the conventional stretchable device, the inventor of the present application has found that there is a matter to be improved in the following point. Specifically, if positional accuracy between a via used to interconnect the two stretchable wirings and an electrode portion of the second stretchable wiring on the upper side is not constant, it may be difficult to improve connection reliability between an electrode portion of the first stretchable wiring on the lower side and the electrode portion of the second stretchable wiring on the upper side. In particular, in a case where the entire device stretches and contracts like a stretchable device, positional deviation is likely to occur, and thus high connection reliability is required.

In view of the above, an object of the present disclosure is to provide a stretchable device in which connection reliability between electrode portions of two stretchable wirings adjacent to each other can be improved.

To achieve the above object, in one embodiment of the present disclosure, there is provided a stretchable device including: a stretchable substrate; a first stretchable wiring on the stretchable substrate and having a first electrode portion; a second stretchable wiring on the first stretchable wiring and having a second electrode portion; and an interlayer sheet between the first stretchable wiring and the second stretchable wiring, in which the interlayer sheet includes a sheet portion and at least one first via portion in the sheet portion, and the first via portion has in a part thereof a connection region connecting the first electrode portion and the second electrode portion.

According to the stretchable device according to one embodiment of the present disclosure, it is possible to improve connection reliability between electrode portions of two stretchable wirings adjacent to each other.

### BRIEF EXPLANATION OF THE DRAWINGS

FIG. 1 is a plan view schematically illustrating a stretchable device according to a first embodiment of the present disclosure.

FIG. 2A is a plan view schematically illustrating the stretchable device according to a second embodiment of the present disclosure.

FIG. 2B is a plan view schematically illustrating a variation of the stretchable device according to the second embodiment of the present disclosure.

FIG. 3A is a plan view schematically illustrating Step 1 of a method of producing the stretchable device according to the second embodiment of the present disclosure.

FIG. 3B is a plan view schematically illustrating Step 2 of the method of producing the stretchable device according to the second embodiment of the present disclosure.

FIG. 3C is a plan view schematically illustrating Step 3 of the method of producing the stretchable device according to the second embodiment of the present disclosure.

FIG. 3D is a plan view schematically illustrating Step 4 of the method of producing the stretchable device according to the second embodiment of the present disclosure.

FIG. 3E is a plan view schematically illustrating Step 5 of the method of producing the stretchable device according to the second embodiment of the present disclosure.

FIG. 4A is a plan view schematically illustrating Step 1 of a method of producing the variation of the stretchable device according to the second embodiment of the present disclosure.

FIG. 4B is a plan view schematically illustrating Step 2 of the method of producing the variation of the stretchable device according to the second embodiment of the present disclosure.

FIG. 4C is a plan view schematically illustrating Step 3 of the method of producing the variation of the stretchable device according to the second embodiment of the present disclosure.

FIG. 4D is a plan view schematically illustrating Step 4 of the method of producing the variation of the stretchable device according to the second embodiment of the present disclosure.

FIG. 4E is a plan view schematically illustrating Step 5 of the method of producing the variation of the stretchable device according to the second embodiment of the present disclosure.

FIG. 5 is a plan view schematically illustrating a stretchable device according to a third embodiment of the present disclosure.

FIG. 6A is a plan view schematically illustrating a first variation of the stretchable device according to the third embodiment of the present disclosure.

FIG. 6B is a sectional view schematically illustrating a structure between A and A in FIG. 6A.

FIG. 7A is a plan view schematically illustrating a second variation of the stretchable device according to the third embodiment of the present disclosure.

FIG. 7B is a sectional view schematically illustrating a structure between B and B in FIG. 7A.

FIG. 8A is a plan view schematically illustrating a third variation of the stretchable device according to the third embodiment of the present disclosure.

FIG. 8B is a sectional view schematically illustrating a structure between A and A in FIG. 8A.

FIG. 8C is a sectional view schematically illustrating a structure between B and B in FIG. 8A.

FIG. 9A is a plan view schematically illustrating a fourth variation of the stretchable device according to the third embodiment of the present disclosure.

FIG. 9B is a sectional view schematically illustrating a structure between A and A in FIG. 9A.

FIG. 9C is a sectional view schematically illustrating a structure between B and B in FIG. 9A.

FIG. 10A is a plan view schematically illustrating a fifth variation of the stretchable device according to the third embodiment of the present disclosure.

FIG. 10B is a sectional view schematically illustrating a structure between A and A in FIG. 10A.

FIG. 10C is a sectional view schematically illustrating a structure between B and B in FIG. 10A.

FIG. 11A is a plan view schematically illustrating a sixth variation of the stretchable device according to the third embodiment of the present disclosure.

FIG. 11B is a sectional view schematically illustrating a structure between A and A in FIG. 11A.

FIG. 12A is a plan view schematically illustrating a seventh variation of the stretchable device according to the third embodiment of the present disclosure.

FIG. 12B is a sectional view schematically illustrating a structure between A and A in FIG. 12A.

FIG. 13A is a plan view schematically illustrating Step 1 of a method of producing the stretchable device according to the third embodiment of the present disclosure.

FIG. 13B is a plan view schematically illustrating Step 2 of the method of producing the stretchable device according to the third embodiment of the present disclosure.

FIG. 13C is a plan view schematically illustrating Step 3 of the method of producing the stretchable device according to the third embodiment of the present disclosure.

FIG. 13D is a plan view schematically illustrating Step 4 of the method of producing the stretchable device according to the third embodiment of the present disclosure.

FIG. 13E is an enlarged plan view schematically illustrating Step 5 of the method of producing the stretchable device according to the third embodiment of the present disclosure.

### DESCRIPTION OF THE PREFERRED EMBODIMENTS

Hereinafter, an embodiment of the present disclosure will be described in detail with reference to the drawings. In each embodiment, differences from the description before the embodiment will be mainly described. Particularly, similar functions and effects achieved by similar configurations will not be mentioned sequentially for each of the embodiments. Among constituent elements in the embodiments below, a constituent element not described in an independent claim will be described as an optional constituent element. Further, size and a ratio of size of constituent elements illustrated in the drawings are not necessarily strict. Further, in the drawings, substantially the same configurations are denoted by the same reference numerals, and redundant description may be omitted or simplified.

### First Embodiment

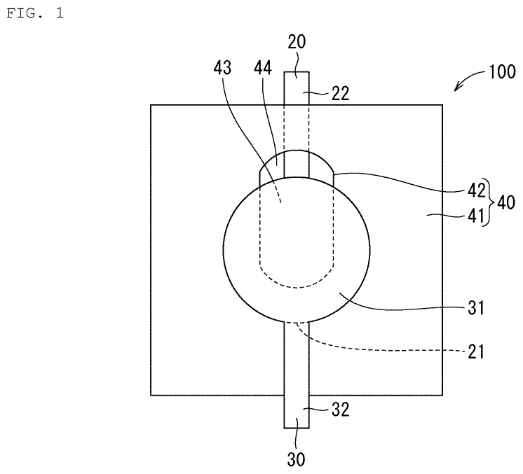

Hereinafter, a configuration of a stretchable device 100 according to a first embodiment of the present disclosure will be described with reference to FIG. 1. FIG. 1 is a plan view schematically illustrating the stretchable device according to the first embodiment of the present disclosure.

The stretchable device 100 according to the first embodiment of the present disclosure includes a stretchable substrate, a first stretchable wiring 20 arranged on the stretchable substrate, a second stretchable wiring 30 arranged on the first stretchable wiring 20, and an interlayer sheet 40 arranged between the first stretchable wiring 20 and the second stretchable wiring 30.

Note that a term “above” in the present description includes a state of an element being located above a certain element, that is, above a certain element with another object interposed therebetween, a state of an element being located above a certain element at an interval, and a state of an element being located immediately above a certain element in contact with the certain element.

For this reason, in the present description, “the first stretchable wiring 20 arranged above a stretchable substrate” includes the first stretchable wiring 20 in a state of being in contact with a main surface of the stretchable substrate, and the first stretchable wiring 20 in a state of being separated from the main surface with another member (for example, a resin layer described later) interposed therebetween without being in direct contact with the main surface of the stretchable substrate.

The resin layer may be formed of, for example, at least one resin material selected from a group including polyimide-based, epoxy-based resin, urethane-based resin, and acrylic-based resin. Further, the resin layer may be formed of an inorganic material such as alumina and silicon dioxide.

Further, the stretchable substrate is a sheet-shaped or film-shaped stretchable substrate, and is composed of, for example, a resin material having stretchability. Examples of the resin material of the stretchable substrate include thermoplastic polyurethane (TPU), a styrene-based elastomer, polyethylene (PE), polystyrene (PS), and polyethylene terephthalate (PET).

A thickness of the stretchable substrate is not particularly limited, but is preferably 100 μm or less, and more preferably is 50 μm or less, from the viewpoint of not inhibiting stretching of a surface of a living body when the device is attached to the living body. Further, the thickness of the stretchable substrate is preferably 20 μm or more from the viewpoint of securing predetermined strength.

Each of the first stretchable wiring 20 and the second stretchable wiring 30 contains conductive particles and resin. Examples of each of the stretchable wirings include a mixture of metal powder of Ag, Cu, Ni, or the like as the conductive particles and elastomer-based resin such as silicone resin. An average particle size of the conductive particles is not particularly limited, but is preferably 0.01 μm to 10 μm. Further, a shape of the conductive particles is preferably spherical.

A thickness of each of the stretchable wirings is not particularly limited, but is preferably 100 μm or less and more preferably is 50 μm or less. Further, the thickness of each of the stretchable wirings is preferably 0.01 μm or more. A line width of each of the stretchable wirings is not particularly limited, but is preferably 0.1 μm or more and more preferably is 10 mm or less. Further, a shape and the like of each of the stretchable wirings are not particularly limited.

Further, the first stretchable wiring 20 has a first electrode portion 21 and a first extending portion 22 extending in a predetermined direction from the first electrode portion 21. The second stretchable wiring 30 has a second electrode portion 31 and a second extending portion 32 extending in a predetermined direction from the second electrode portion 31. In plan view, the first electrode portion 21 and the second electrode portion 31 overlap each other. Further, the first extending portion 22 and the second extending portion 32 may extend in directions opposite to each other. Without being limited by the above, the first extending portion 22 and the second extending portion 32 may extend in the same direction.

In the present embodiment, the first electrode portion 21 and the second electrode portion 31 may have the same size and the same shape in plan view. A planar shape of each electrode portion may be, for example, circular shapes such as a true circle or an ellipse, a polygon, or the like.

However, the present disclosure is not limited to the above, and as described in a section of another embodiment to be described later, planar sizes of these constituent elements are not necessarily the same, and the first electrode portion 21 located on the lower layer side may be larger than the second electrode portion 31, and the stretchable substrate located on the lower layer side may be larger than the interlayer sheet. Further, planar shapes of these constituent elements are not necessarily the same.

The interlayer sheet 40 includes a sheet portion 41 and at least one first via portion 42 provided in the sheet portion 41. As an example, the interlayer sheet 40 may be constituted by the same material and thickness as those of the stretchable substrate described above. Further, the stretchable substrate and the interlayer sheet may have the same size and the same shape in plan view. A planar shape of each of the stretchable substrate and the interlayer sheet may be, for example, a rectangle, a square, a polygon, or the like.

On the premise of the above configuration, the present disclosure is characterized in that the first via portion 42 has in part a connection region 43 connecting the first electrode portion 21 and the second electrode portion 31.

According to this characteristic, in addition to the connection region 43, the first via portion 42 includes a non-connection region 44 that does not connect the first electrode portion 21 and the second electrode portion 31. That is, the second electrode portion 31 overlaps a part of the first via portion 42 in plan view (as viewed from a thickness direction of the stretchable substrate).

From another point of view, the non-connection region 44 of the first via portion 42 is located outside the second electrode portion 31 in plan view. From still another point of view, the connection region 43 occupies a part of the first via portion 42 in plan view.

As described above, in the present disclosure, the first via portion 42 is not constituted as a whole by the connection region 43, but a part of the first via portion 42 constitutes the connection region 43, and the other portion constitutes the non-connection region 44 that does not connect the first electrode portion 21 and the second electrode portion 31.

For this reason, a position of the second electrode portion 31 is such a position that the connection region 43 and the non-connection region 44 are provided, and a positional relationship between the first via portion 42 and the second electrode portion 31 may be determined as a whole.

By this, positional accuracy between the first via portion 42 and the second electrode portion 31 can be suitably secured, and as a result, connection reliability between the first electrode portion 21 of the first stretchable wiring 20 located on the lower side and the second electrode portion 31 of the second stretchable wiring on the upper side can be improved.

Further, in the stretchable device 100, since the entire device stretches and contracts, positional displacement is likely to occur, but also in a case where positional displacement occurs, at a portion where the non-connection region is located before the positional displacement, the connection region may be located after the positional displacement. For this reason, also in a case where the entire device stretches and contracts, high connection reliability can be secured.

Note that the stretchable device 100 can further include an adhesive layer. The adhesive layer has adhesiveness that allows the stretchable device 100 to be attached to an adherend such as a living body. In one example, the adhesive layer may be positioned between the stretchable substrate and an adherend such as a living body.

The adhesive layer includes a first main surface on the side of an adherend such as a living body and a second main surface on the side opposite to the first main surface. A first adhesive layer preferably has adhesiveness on both main surfaces. The first main surface of the adhesive layer can be attached to a living body or the like. Note that it is also possible to employ an aspect in which the first main surface itself of the adhesive layer is attached to another layer, and then another layer is attached to a living body or the like. The second main surface of the adhesive layer can be attached to the stretchable substrate. Note that a protective layer may be further arranged between the second main surface of the adhesive layer and the stretchable substrate from the viewpoint of improving waterproofness and the like.

The adhesive layer can be used without any particular limitation as long as it is an adhesive that is mild to skin, has sufficient pressure-sensitive adhesiveness, and can be easily peeled off from the skin after use.

Although not particularly limited, the adhesive layer may be constituted by a pressure-sensitive adhesive or the like. The pressure-sensitive adhesive is not particularly limited as long as it can be laminated above the stretchable substrate and generally used. For example, as the pressure-sensitive adhesive, a rubber-based, an acrylic-based, or a silicone-based adhesive can be used. In a case where the pressure-sensitive adhesive is used, bonding to a mating member (stretchable substrate) can be performed at a relatively low temperature, so that change in quality and distortion of the stretchable substrate by use of excessive heat and UV energy can be prevented.

### Second Embodiment

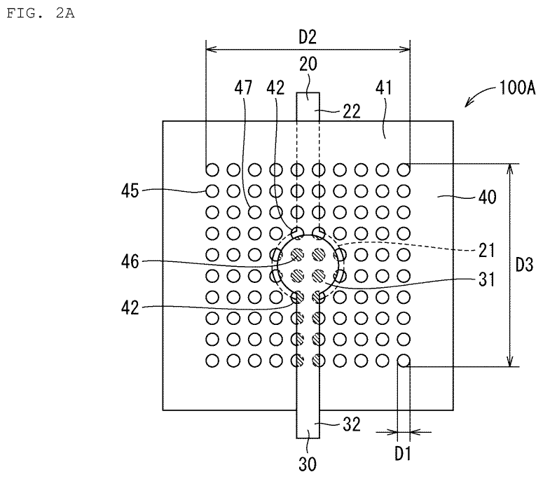

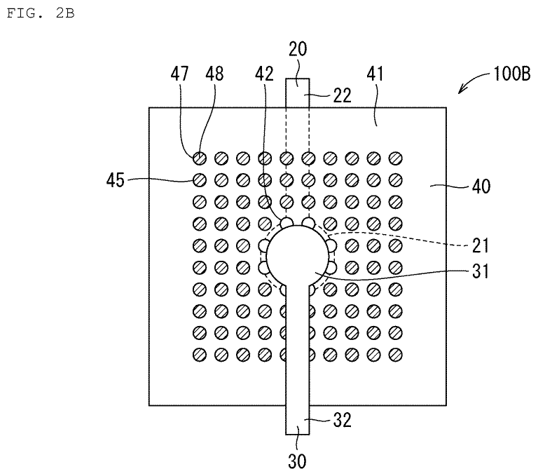

Hereinafter, a configuration of a stretchable device 100A according to a second embodiment of the present disclosure will be described with reference to FIG. 2A. FIG. 2A is a plan view schematically illustrating the stretchable device according to the second embodiment of the present disclosure.

The second embodiment is different from the first embodiment in that the interlayer sheet 40 includes a plurality of via portions 45.

The via portion 45 has a smaller planar size than each electrode portion. Further, the planar size of the via portion 45 is smaller than a width (short dimension) of the extending portion of each wiring. Further, the via portions 45 may be regularly arranged at predetermined intervals on the sheet portion 41 in plan view. Examples of the regular arrangement include a matrix-like arrangement. That is, the interlayer sheet 40 has an aggregate of the via portions 45.

A planar shape of the via portion 45 may be, for example, circular shapes such as a true circle or an ellipse, a polygon, or the like. In a case where the planar shape of the via portion 45 is a circular shape, a diameter size D1 of the portion is, for example, 10 μm to 500 μm, and may be, for example, 50 μm to 300 μm in consideration of ease of filling with a material. Further, in a case where the aggregate of the via portions 45 is arranged in a matrix arrangement, sizes D2 and D3 in vertical and horizontal directions are 2 mm to 20 mm, and may be, for example, 5 mm.

Further, a plurality of the via portions 45 include a second via portion 46 and a third via portion 47 in addition to the first via portion 42 described in the first embodiment. The number of each of the first to third via portions may be two or more. In the second embodiment, similarly to the first embodiment, as illustrated in FIG. 2A, the first via portion 42 is a via portion having in part a connection region connecting the first electrode portion 21 and the second electrode portion 31. That is, the first via portion 42 is a via portion overlapping in part the second electrode portion 31 in plan view. In FIG. 2A, the first via portion 42 corresponds to a via portion hatched in part in one via.

The second via portion 46 may be a via portion that overlaps as a whole the second electrode portion 31 in plan view. In FIG. 2A, the second via portion 46 corresponds to a via portion hatched as a whole in one via. Note that the second via portion 46 may be a via portion overlapping in part the second electrode portion 31 in plan view. The second via portion 46 includes a connection region connecting the first electrode portion 21 and the second electrode portion 31 as compared with the first via portion 42.

That is, the second via portion 46 does not need to have a non-connection region that does not connect the first electrode portion 21 and the second electrode portion 31. Further, the second via portion 46 is in contact with the second electrode portion 31 and is located below the second electrode portion 31. Due to the presence of the second via portions 46, connection reliability between the two electrode portions can be improved.

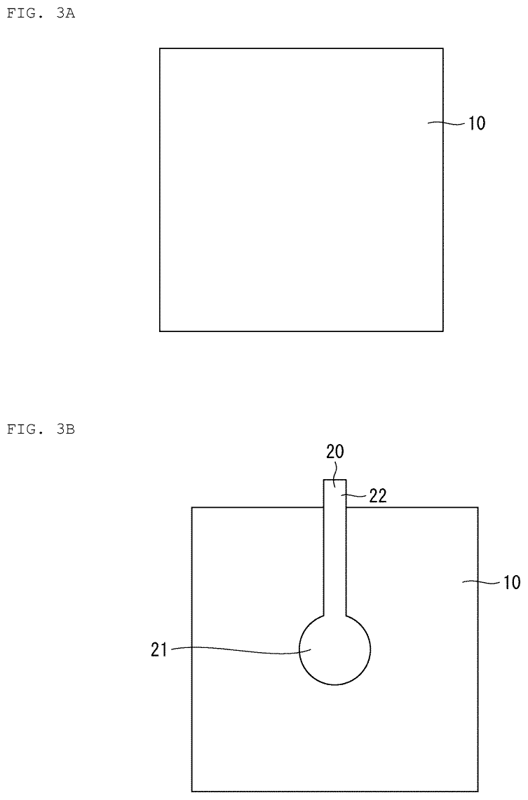

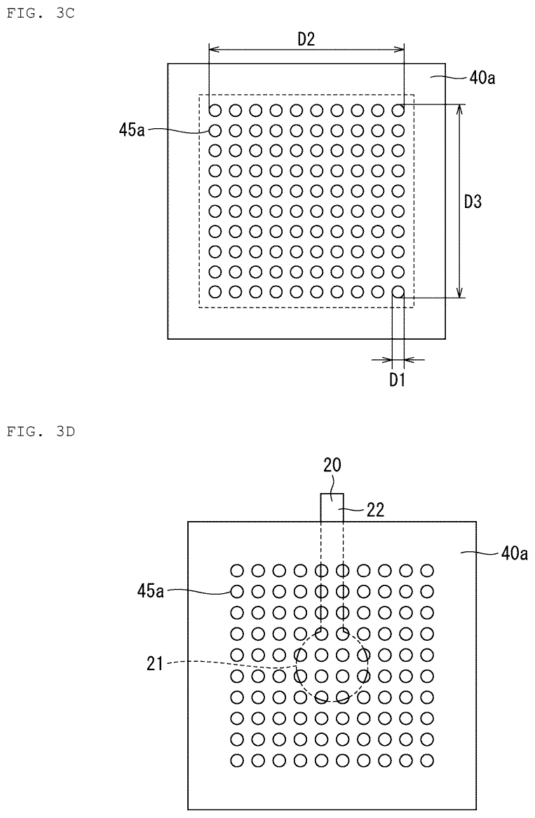

Note that, in FIG. 2A used in the present embodiment and FIG. 3E described later corresponding to FIG. 2A, in order to improve understanding of a positional relationship and a configuration of the second via portion, the second via portion located below the second electrode portion is indicated by a dotted line. Note that, other than these drawings, in a related drawing of the stretchable device having the second via portion, the second via portion located below the second electrode portion is not illustrated in consideration of visibility of each drawing.

The third via portion 47 is a via portion that does not overlap the second electrode portion 31 in plan view. In the second embodiment, the third via portion 47 may be a via hole. In FIG. 2A, the third via portion 47 corresponds to a non-hatched via portion in one via.

As described above, the planar size of the via portion 45 is smaller than the planar size of each electrode portion. For this reason, a plurality of the via portions 45, specifically, the connection regions of a plurality of the first via portions and a plurality of the second via portions 46 can be positioned between the first electrode portion 21 and the second electrode portion 31 in plan view.

As a result, a plurality of connection regions connecting the first electrode portion 21 and the second electrode portion 31 are present between these electrode portions, and connection reliability between the first electrode portion 21 and the second electrode portion 31 can be improved.

Also if a ratio of the connection region to any of the second via portions 46 among a plurality of the second via portions 46 is small between the first electrode portion 21 and the second electrode portion 31, and it is difficult to secure interlayer connection between the electrode portions in that portion, the interlayer connection between the electrode portions can be suitably secured by the presence of a plurality of other ones of the second via portions 46.

Further, as described above, since the planar size of the via portion 45 is smaller than a width (short dimension) of the extending portion of each wiring, it is possible to avoid breakage starting from a portion where the second extending portion 32 of the second stretchable wiring 30 overlaps an edge portion of the via portion 45 in plan view.

Furthermore, since there are a plurality of the connection regions that connect the first electrode portion 21 and the second electrode portion 31 between these electrode portions, a plurality of the connection regions can provide an anchor effect to the second electrode portion 31. By this, adhesion between the second electrode portion 31 and the interlayer sheet 40 having a plurality of connection regions can be improved.

Hereinafter, a method of producing the stretchable device 100A according to the second embodiment will be described.

### Step 1

FIG. 3A is a plan view schematically illustrating Step 1 of a method of producing the stretchable device according to the second embodiment of the present disclosure. First, as illustrated in FIG. 3A, a stretchable substrate 10 is prepared.

### Step 2

FIG. 3B is a plan view schematically illustrating Step 2 of the method of producing the stretchable device according to the second embodiment of the present disclosure. Next, as illustrated in FIG. 3B, after Step 1 is performed, a wiring material is screen-printed on the stretchable substrate 10 using a squeegee or the like, and then dried at about 100° C. for predetermined time by drying. In this manner, the first stretchable wiring 20 can be formed on the stretchable substrate 10.

### Step 3

FIG. 3C is a plan view schematically illustrating Step 3 of the method of producing the stretchable device according to the second embodiment of the present disclosure. Next, as illustrated in FIG. 3C, after Step 2 is performed, a substrate 40a used as an interlayer sheet is prepared. The substrate 40a may be the same as the stretchable substrate 10 described above. After the above, the substrate 40a is irradiated with a laser beam at a predetermined interval to form via holes 45a having a regular arrangement such as a matrix-like arrangement. As the laser, for example, carbon dioxide gas laser can be used.

As described above, the planar shape of the via hole 45a may be, for example, circular shapes such as a true circle or an ellipse, a polygon, or the like. When the planar shape of the via hole 45a is a circular shape, the diameter size D1 of the hole may be, for example, 10 μm to 500 μm. Further, in a case where an assembly of the via holes 45a is in a matrix arrangement, the sizes D2 and D3 in vertical and horizontal directions of the assembly may be 2 mm to 20 mm, respectively.

### Step 4

FIG. 3D is a plan view schematically illustrating Step 4 of the method of producing the stretchable device according to the second embodiment of the present disclosure. Next, as illustrated in FIG. 3D, after Step 3 is performed, the substrate 40a prepared in the step is bonded to the stretchable substrate 10 with the first stretchable wiring 20. Examples of a bonding means include dry lamination using a vacuum press machine.

### Step 5

FIG. 3E is a plan view schematically illustrating Step 5 of the method of producing the stretchable device according to the second embodiment of the present disclosure. Next, as illustrated in FIG. 3E, after Step 4 is performed, similarly to Step 2, a wiring material is screen-printed at a predetermined position of the substrate 40a as the interlayer sheet so as to be interlayer-connectable to the first electrode portion 21 of the first stretchable wiring 20 through the via hole 45a using a squeegee or the like. After the above, drying is performed at about 100° C. for predetermined time by drying. By this, the second stretchable wiring 30 can be formed on the obtained interlayer sheet 40.

Note that, in the present description, a through hole formed in the substrate 40a in the middle of production is referred to as the via hole 45a, and the through hole is referred to as the via portion 45 in a production completion stage. The use of this expression is based on the fact that, as described above, a plurality of the obtained via portions 45 include the first via portions 42 (filled in part with the wiring material), the second via portions 46 (filled as a whole with the wiring material), and the third via portion (one that is not filled with the wiring material and remains in a state of a via hole).

By the above, the stretchable device 100A according to the second embodiment can be produced. [Variation of second embodiment]

Hereinafter, a configuration of a variation of the stretchable device according to the second embodiment of the present disclosure will be described with reference to FIG. 2B. FIG. 2B is a plan view schematically illustrating the variation of the stretchable device according to the second embodiment of the present disclosure.

The variation of the second embodiment is different from the second embodiment in that the via portion 45 has a conductive material 48 in the inside in advance. The conductive material may be the same as the wiring material described above. A fact that the conductive material is provided in advance in the via portion 45 means that the conductive material is also provided in advance at least in a portion to be the second via portion that may overlap the second electrode portion in addition to a portion to be the third via portion in a stage before formation of the second stretchable wiring. Note that, in FIG. 2B, the third via portion 47 after formation corresponds to a via portion hatched as a whole in a different direction as compared with the second via portion 46 illustrated in FIG. 2A in one via portion.

This makes it possible to avoid occurrence of a filling defect of the wiring material (corresponding to the conductive material) in the via portion. Further, it is easy to find a filling defect of the material. Note that, in a stage before the second stretchable wiring is formed, the conductive material does not need to be provided in advance to the portion that may be the first via portion.

Hereinafter, a method of producing a stretchable device 100B (variation of the second embodiment) according to the second embodiment will be described. Note that description of a portion overlapping the portion described in the section of the method of producing the stretchable device 100A will be omitted or simplified.

### Step 1

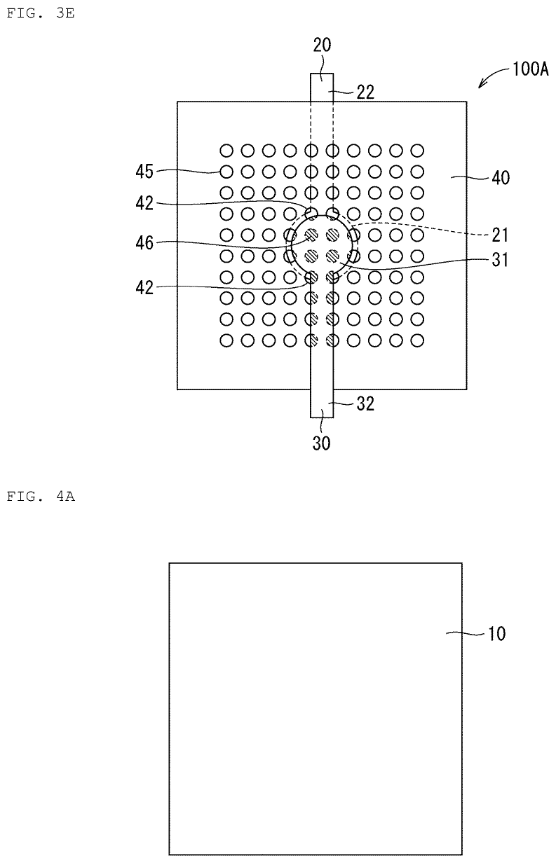

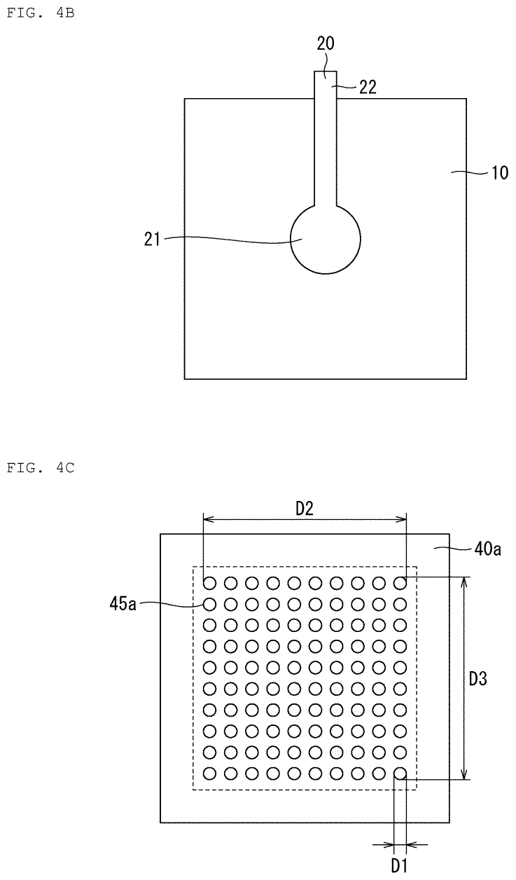

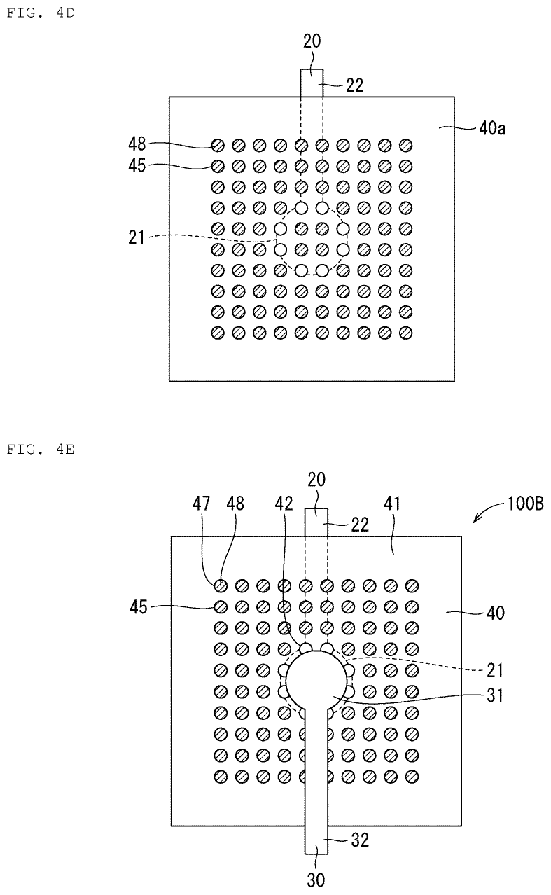

FIG. 4A is a plan view schematically illustrating Step 1 of a method of producing the variation of the stretchable device according to the second embodiment of the present disclosure. First, as illustrated in FIG. 4A, the stretchable substrate 10 is prepared.

### Step 2

FIG. 4B is a plan view schematically illustrating Step 2 of the method of producing the variation of the stretchable device according to the second embodiment of the present disclosure. Next, as illustrated in FIG. 4B, after Step 1 is performed, a wiring material is screen-printed on the stretchable substrate 10, and then dried. In this manner, the first stretchable wiring 20 can be formed on the stretchable substrate 10.

### Step 3

FIG. 4C is a plan view schematically illustrating Step 3 of the method of producing the variation of the stretchable device according to the second embodiment of the present disclosure. Next, as illustrated in FIG. 4C, after Step 2 is performed, the substrate 40a used as an interlayer sheet is prepared. After the above, the substrate 40a is irradiated with a laser beam at a predetermined interval to form a plurality of the via holes 45a having a regular arrangement. Furthermore, after the above, a predetermined portion of a plurality of the via holes 45a is filled with a conductive material. As a filling means, for example, the via hole can be filled with the conductive material by use of screen printing. As a filling position, at least a portion to be the third via portion and a portion to be the second via portion in the finally obtained device are filled with the conductive material in advance.

### Step 4

FIG. 4D is a plan view schematically illustrating Step 4 of the method of producing the variation of the stretchable device according to the second embodiment of the present disclosure. Next, as illustrated in FIG. 4D, after Step 3 is performed, the substrate 40a prepared in the step is bonded to the stretchable substrate 10 with the first stretchable wiring 20. After the substrate 40a is bonded, a predetermined portion of a plurality of the via holes 45a may be filled with a conductive material.

### Step 5

FIG. 4E is a plan view schematically illustrating Step 5 of the method of producing the variation of the stretchable device according to the second embodiment of the present disclosure. Next, as illustrated in FIG. 4E, after Step 4 is performed, similarly to Step 2, a wiring material is screen-printed at a predetermined position of the substrate 40a as the interlayer sheet so as to be interlayer-connectable to the first electrode portion 21 of the first stretchable wiring 20 through the via hole 45a. After the above, drying is performed. By this, the second stretchable wiring 30 can be formed on the obtained interlayer sheet 40.

By the above, the stretchable device 100B according to the second embodiment can be produced.

### Third Embodiment

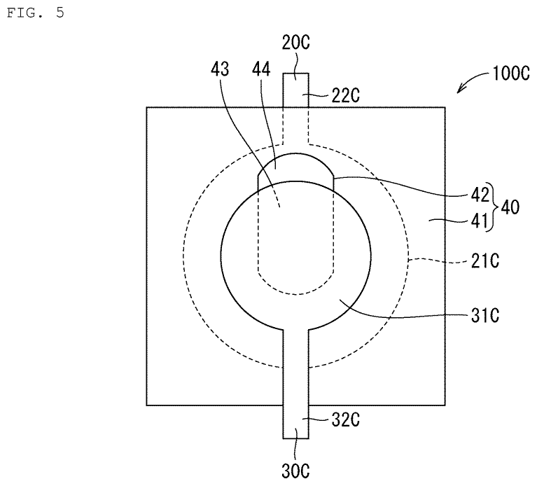

Hereinafter, a configuration of a stretchable device 100C according to a third embodiment of the present disclosure will be described with reference to FIG. 5. FIG. 5 is a plan view schematically illustrating the stretchable device according to the third embodiment of the present disclosure.

The stretchable device 100C in the third embodiment has basically the same configuration as that of the first embodiment. As an example, as illustrated in FIG. 5, a difference from the first embodiment is that a planar size of a second electrode portion 31C of a second stretchable wiring 30C is smaller than a planar size of a first electrode portion 21C of a first stretchable wiring 20C.

Also in this case, similarly to the first embodiment, a part of the first via portion 42 constitutes the connection region 43, and the other portions constitute the non-connection region 44 that does not connect the first electrode portion 21C and the second electrode portion 31C. For this reason, a position of the second electrode portion 31C is such a position that the connection region 43 and the non-connection region 44 are provided, and a positional relationship between the first via portion 42 and the second electrode portion 31C may be determined as a whole.

By this, positional accuracy between the first via portion 42 and the second electrode portion 31C can be suitably secured, and as a result, connection reliability between the first electrode portion 21C of the first stretchable wiring 20C located on the lower side and the second electrode portion 31C of the second stretchable wiring 30C on the upper side can be improved.

Further, in the stretchable device finally obtained, in order for a part of the first via portion 42 to constitute the connection region 43 and for the other portions to constitute the non-connection region 44 that does not connect the first electrode portion 21C and the second electrode portion 31C, a wiring material is formed so as not to cover or overlap the entire via hole in plan view at the time of formation of the second stretchable wiring in the middle of production of the stretchable device. By this, an air escape path located in the via hole can be secured, and occurrence of residual air bubbles (also referred to as voids) in the via portion including the connection region 43 including the obtained wiring material (corresponding to the conductive material) can be suppressed.

### First Variation of Third Embodiment

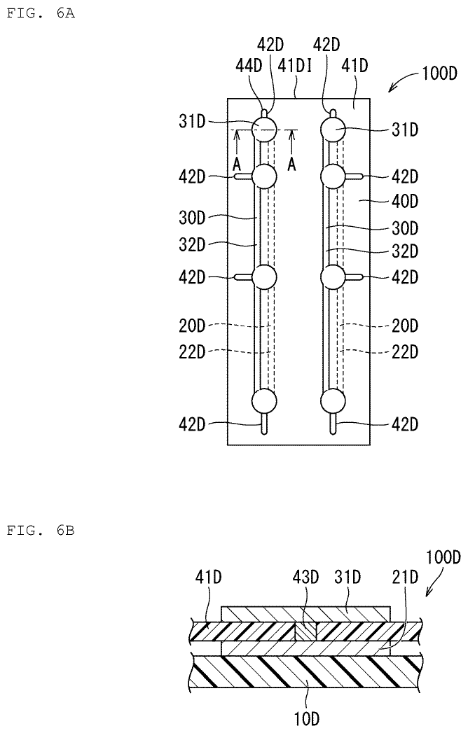

Hereinafter, a configuration of a first variation of the stretchable device according to the third embodiment of the present disclosure will be described with reference to FIGS. 6A and 6B.

FIG. 6A is a plan view schematically illustrating the first variation of the stretchable device according to the third embodiment of the present disclosure. FIG. 6B is a sectional view schematically illustrating a structure between A and A in FIG. 6A.

The first variation is characterized in that a non-connection region 44D of a first via portion 42D extends from a second electrode portion 31D toward an edge portion 41DI of an interlayer sheet 40D in plan view. Further, as illustrated, each of a first stretchable wiring 20D and a second stretchable wiring 30D includes two or more electrode portions 21D and 31D.

According to the characteristic, a direction of the non-connection region 44D of the first via portion 42D can be made constant. Further, it is easy to sufficiently secure the size of the non-connection region 44D between the electrode portion and the edge portion 41DI of the interlayer sheet 40D. As a result, a positional relationship between the first via portion 42D and the second electrode portion 31D can be made clearer. By this, positional accuracy between the first via portion 42D and the second electrode portion 31D can be more suitably secured.

Further, at the time of formation of the second stretchable wiring 30D in the middle of production of a stretchable device 100D, an air escape path located in the via hole can be easily secured, and occurrence of residual air bubbles in the via portion including a connection region 43D including the obtained wiring material (corresponding to the conductive material) can be further suppressed. [Second variation of third embodiment]

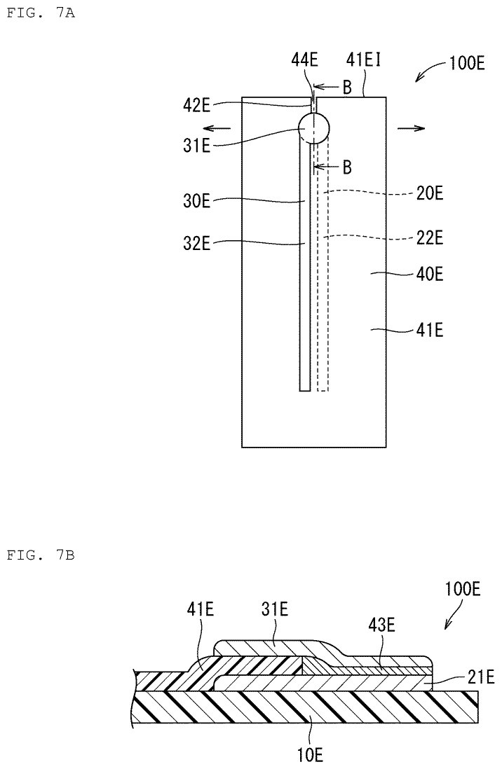

Hereinafter, a configuration of a second variation of the stretchable device according to the third embodiment of the present disclosure will be described with reference to FIGS. 7A and 7B.

FIG. 7A is a plan view schematically illustrating the second variation of the stretchable device according to the third embodiment of the present disclosure. FIG. 7B is a sectional view schematically illustrating a structure between B and B in FIG. 7A.

The second variation is characterized in that a non-connection region 44E of the first via portion 42E is continuous from a second electrode portion 31E to an edge portion 41EI of an interlayer sheet 40E in plan view.

According to this characteristic, the interlayer sheet 40E is divided in part with the non-connection region 44E of the first via portion 42E as a starting point. By this, when stretching force acts in an arrow direction illustrated in FIG. 7A, the stretching force hardly acts on the stretchable wiring located at a central portion of a stretchable device 100E in plan view. By this, stretching and contraction of the wiring can be suppressed, and a change in wiring resistance can be reduced. Further, when a via is formed in this portion, cutting chips are less likely to remain in the via portion. For this reason, a size of the via portion can be easily secured at a predetermined size.

### Third Variation of Third Embodiment

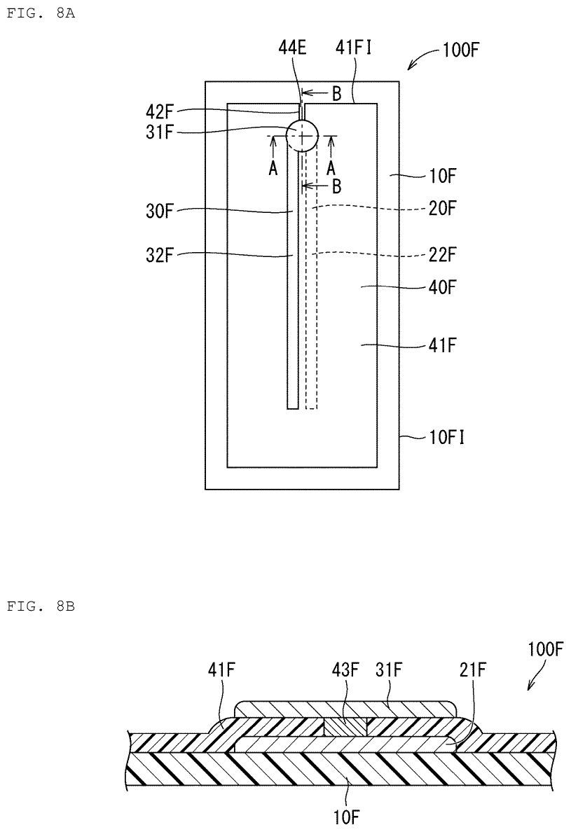

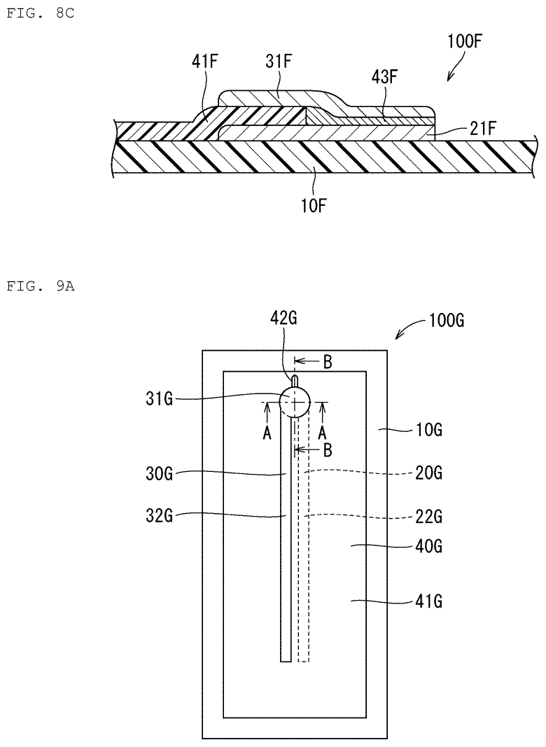

Hereinafter, a configuration of a third variation of the stretchable device according to the third embodiment of the present disclosure will be described with reference to FIGS. 8A to 8C.

FIG. 8A is a plan view schematically illustrating the third variation of the stretchable device according to the third embodiment of the present disclosure. FIG. 8B is a sectional view schematically illustrating a structure between A and A in FIG. 8A. FIG. 8C is a sectional view schematically illustrating a structure between B and B in FIG. 8A.

The third variation is characterized in that an edge portion 41FI of an interlayer sheet 40F is located further on the inside than an edge portion 10FI of a stretchable substrate 10F in plan view. According to this characteristic, since a planar size of the interlayer sheet 40F is smaller than a planar size of the stretchable substrate 10F, highly accurate joining is not required at the time of joining the interlayer sheet 40F to the stretchable substrate 10F, which is preferable from the viewpoint of manufacturing efficiency. Further, in the stretchable device, also if there is external contact in a longitudinal extending direction of the substrate, direct contact of the interlayer sheet 40F can be avoided.

### Fourth Variation of Third Embodiment

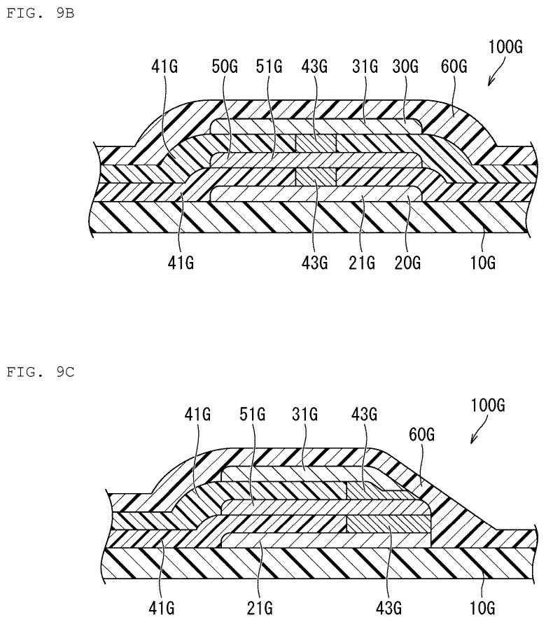

Hereinafter, a configuration of a fourth variation of the stretchable device according to the third embodiment of the present disclosure will be described with reference to FIGS. 9A to 9C.

FIG. 9A is a plan view schematically illustrating the fourth variation of the stretchable device according to the third embodiment of the present disclosure. FIG. 9B is a sectional view schematically illustrating a structure between A and A in FIG. 9A. FIG. 9C is a sectional view schematically illustrating a structure between B and B in FIG. 9A.

The fourth variation is characterized in that three or more stretchable wirings are arranged in a thickness direction of a stretchable substrate 10G, and an electrode portion of one of adjacent stretchable wirings and an electrode portion of the other stretchable wiring are connected to each other through a first via portion 42G of an interlayer sheet 40G.

As an example, as illustrated, a stretchable device 100G includes a first stretchable wiring 20G, a second stretchable wiring 30G, and a third stretchable wiring 50G arranged between the first stretchable wiring 20G and the second stretchable wiring 30G in a thickness direction of the stretchable substrate 10.

According to this characteristic, also in a case where three or more stretchable wirings are arranged, between two stretchable wirings adjacent to each other, a part of the first via portion 42G constitutes a connection region 43G, and the other portions constitute a non-connection region 44G that does not connect a first electrode portion 21G and a second electrode portion 31G. For this reason, as a whole, a positional relationship between the first via portion 42G and the second electrode portion 31G may be determined. By this, positional accuracy between the first via portion 42G and the second electrode portion 31G can be suitably secured.

Further, a wiring material is formed so as not to cover or overlap the entire via hole in plan view at the time of formation of the stretchable wiring positioned on the upper side of two stretchable wirings adjacent to each other in the middle of production of the stretchable device. By this, an air escape path located in the via hole can be secured, and occurrence of residual air bubbles (also referred to as voids) in the via portion including the connection region 43G including the obtained wiring material (corresponding to the conductive material) can be suppressed.

### Fifth Variation of Third Embodiment

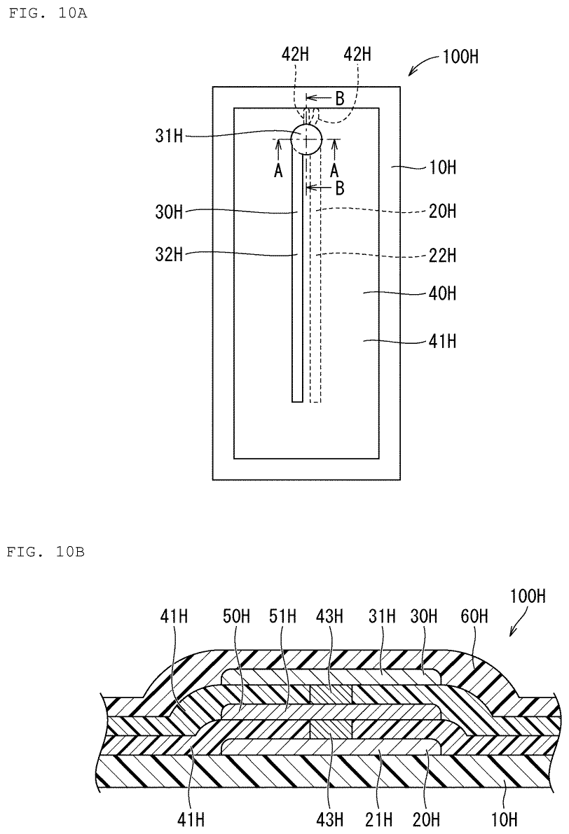

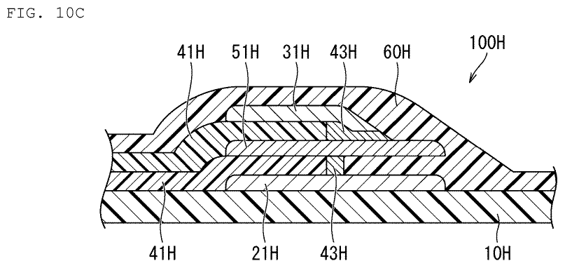

Hereinafter, a configuration of a fifth variation of the stretchable device according to the third embodiment of the present disclosure will be described with reference to FIGS. 10A to 10C.

FIG. 10A is a plan view schematically illustrating the fifth variation of the stretchable device according to the third embodiment of the present disclosure. FIG. 10B is a sectional view schematically illustrating a structure between A and A in FIG. 10A. FIG. 10C is a sectional view schematically illustrating a structure between B and B in FIG. 10A.

The fifth variation is characterized in that two or more first via portions 42H in which non-connection regions 44H are arranged to be shifted in plan view are provided as compared with the fourth variation.

Since a wiring material or a conductive material is not present in the non-connection region 44H of the first via portion 42H, in a case where three or more stretchable wirings are arranged in a thickness direction of a stretchable substrate 10H, if there is a positional relationship in which the non-connection regions 44H of two or more of the first via portions 42H overlap each other in plan view, thickness in a local region of the interlayer sheet tends to be non-uniform as compared with thickness of other regions.

In this regard, according to the above characteristic, since the non-connection regions 44H of two or more of the first via portions 42H are in a positional relationship of being shifted from each other in plan view, it is possible to prevent thickness of a local region of the interlayer sheet from becoming non-uniform as compared with thickness of other regions.

### Sixth Variation of Third Embodiment

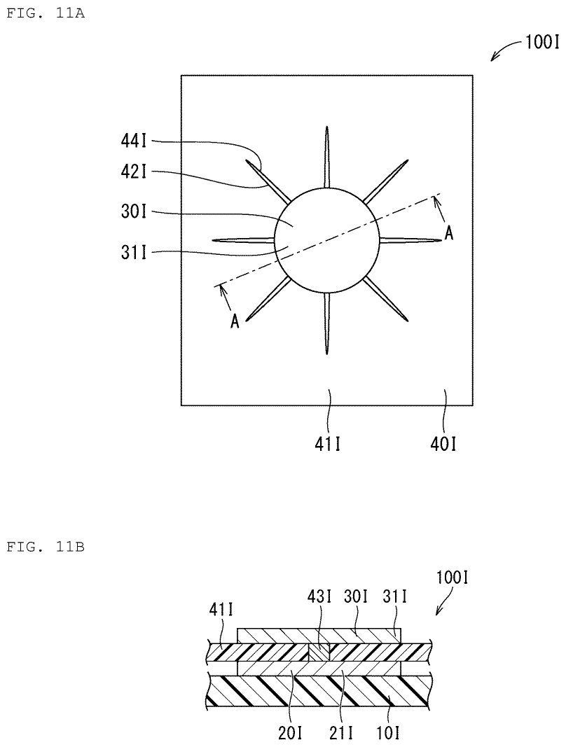

Hereinafter, a configuration of a sixth variation of the stretchable device according to the third embodiment of the present disclosure will be described with reference to FIGS. 11A and 11B.

FIG. 11A is a plan view schematically illustrating the sixth variation of the stretchable device according to the third embodiment of the present disclosure. FIG. 11B is a sectional view schematically illustrating a structure between A and A in FIG. 11A.

The sixth variation is characterized in that a plurality of first via portions 42I are located below a single first electrode portion 31I in plan view.

According to this characteristic, since there are a plurality of the first via portions 421, an area of a connection region 43I can be made large as compared with a case of a single first via portion. By this, reliability of interlayer connection can be further improved. Further, at the time of production of the stretchable device, it is possible to lower the requirement for accuracy of alignment when an interlayer sheet 401 is joined to a stretchable substrate 10I and for positional accuracy of the second stretchable wiring formed at a predetermined position of the interlayer sheet 40I.

### Seventh Variation of Third Embodiment

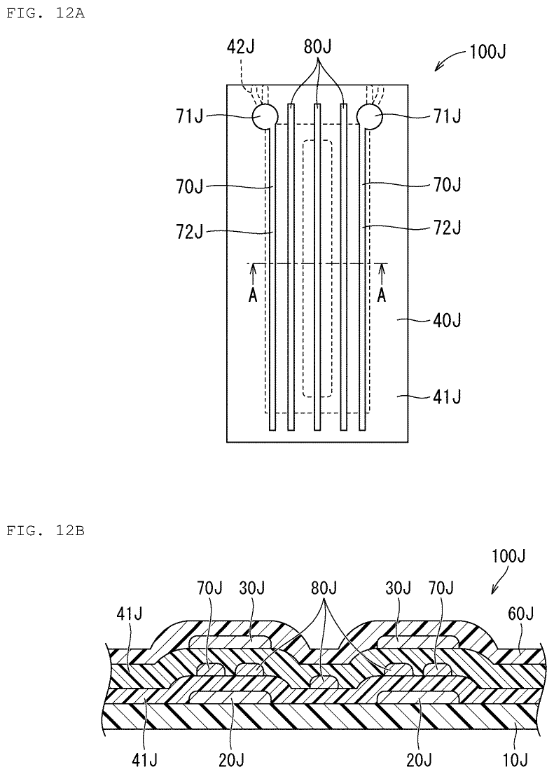

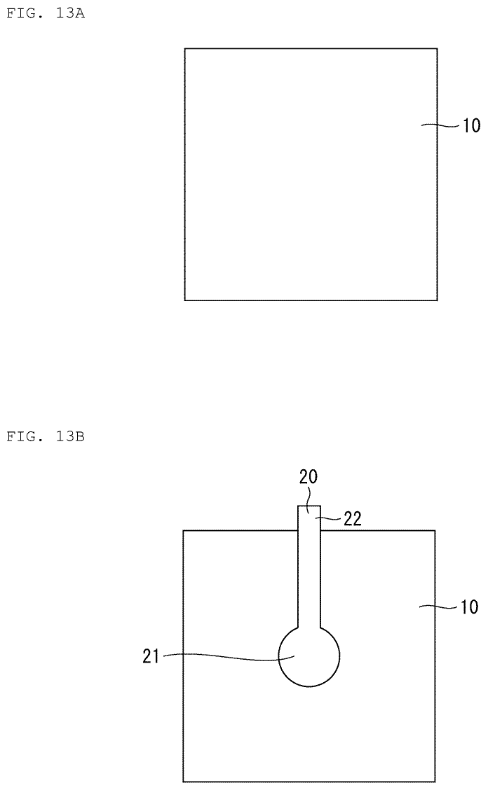

Hereinafter, a configuration of a seventh variation of the stretchable device according to the third embodiment of the present disclosure will be described with reference to FIGS. 12A and 12B.

FIG. 12A is a plan view schematically illustrating the seventh variation of the stretchable device according to the third embodiment of the present disclosure. FIG. 12B is a sectional view schematically illustrating a structure between A and A in FIG. 12A.

Note that FIG. 12A is a diagram mainly emphasizing arrangement and a structure of a plurality of internal stretchable wirings located between a first stretchable wiring 20J and a second stretchable wiring 30J in consideration of clarity of the drawing. That is, in FIG. 12A, the second stretchable wiring is omitted.

The seventh variation is the same as the fourth variation in that three or more stretchable wirings are arranged in a thickness direction of a stretchable substrate 10J, but a plurality of internal stretchable wirings 70J and 80J located between the first stretchable wiring 20J and the second stretchable wiring 30J are located in a longitudinal extending direction of an interlayer sheet 40J.

In one example, the stretchable wirings 70J and 80J having a small region area are arranged inside the device between two of the stretchable wirings 20J and 30J having a large region area in a thickness direction of the stretchable substrate 10J. The stretchable wirings 70J and 80J may be arranged in parallel at a predetermined interval on the interlayer sheet 40J.

Some of the stretchable wirings 70J are interlayer connected to the first stretchable wiring 20J and the second stretchable wiring 30J via connection regions of via portions. On the other hand, the remaining stretchable wiring 80J functions as a separate and independent wiring without being connected to the first stretchable wiring 20J and the second stretchable wiring 30J. That is, the remaining stretchable wiring 80J located inside functions as a stretchable wiring that is not in contact with a first via portion 42J.

According to such a characteristic, the first stretchable wiring and the second stretchable wiring can block noise that may intrude into the internal stretchable wiring. Further, since two or more types of wirings or wiring groups having different functions can be provided in a single stretchable device 100J, it is advantageous in that a device function can be enriched.

Hereinafter, a method of producing the stretchable device 100C according to the third embodiment (basic mode) illustrated in FIG. 5 will be described. Note that description of a portion overlapping content regarding the method of producing the stretchable device described above will be omitted or simplified.

### Step 1

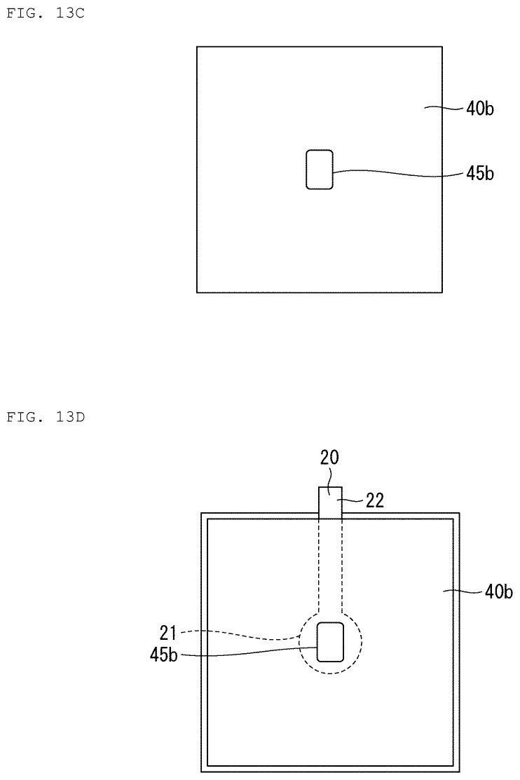

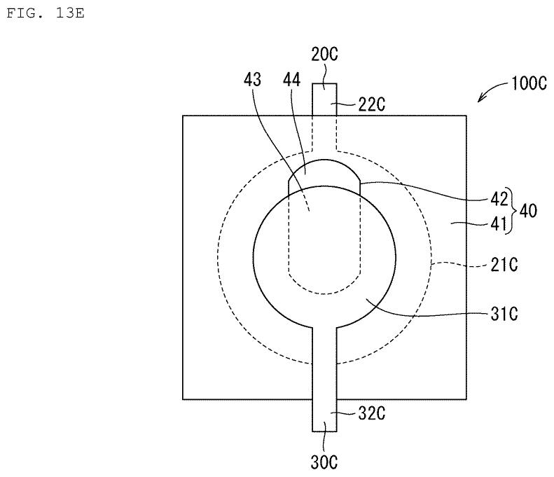

FIG. 13A is a plan view schematically illustrating Step 1 of a method of producing the stretchable device according to the third embodiment of the present disclosure. First, as illustrated in FIG. 13A, the stretchable substrate 10 is prepared.

### Step 2

FIG. 13B is a plan view schematically illustrating Step 2 of the method of producing the stretchable device according to the third embodiment of the present disclosure. Next, as illustrated in FIG. 13B, after Step 1 is performed, a wiring material is screen-printed on the stretchable substrate 10, and then dried. In this manner, the first stretchable wiring 20 can be formed on the stretchable substrate 10.

### Step 3

FIG. 13C is a plan view schematically illustrating Step 3 of the method of producing the stretchable device according to the third embodiment of the present disclosure. Next, as illustrated in FIG. 13C, after Step 2 is performed, a substrate 40b used as an interlayer sheet is prepared. After the above, the substrate 40b is irradiated with laser to form a via hole 45b.

### Step 4

FIG. 13D is a plan view schematically illustrating Step 4 of the method of producing the stretchable device according to the third embodiment of the present disclosure. Next, as illustrated in FIG. 13D, after Step 3 is performed, the substrate 40b prepared in the step is bonded to the stretchable substrate 10 with the first stretchable wiring 20.

### Step 5

FIG. 13E is a plan view schematically illustrating Step 5 of the method of producing the stretchable device according to the third embodiment of the present disclosure. Next, as illustrated in FIG. 13E, after Step 4 is performed, similarly to Step 2, a wiring material is screen-printed at a predetermined position of the substrate 40b as the interlayer sheet so as to be interlayer-connectable to the first electrode portion 21C of the first stretchable wiring 20C through the via hole 45b using a squeegee or the like. After the above, drying is performed. By this, the second stretchable wiring 30C can be formed on the obtained interlayer sheet 40.

Specifically, in the present method of production, in the stretchable device finally obtained in Step 5, a wiring material is printed and applied so as not to cover or overlap the entire via hole in plan view so that a part of the first via portion 42 constitutes the connection region 43 and the other portion constitutes the non-connection region 44 that does not connect the first electrode portion 21C and the second electrode portion 31C.

By this, an air escape path located in the via hole can be secured, and occurrence of residual air bubbles (also referred to as voids) in the via portion including the connection region 43 including the obtained wiring material (corresponding to the conductive material) can be suppressed.

By the above, the stretchable device 100C according to the third embodiment can be produced.

Note that each of the embodiments and variations is an example, and the present disclosure is not limited to each of the embodiments and variations. Further, each drawing illustrates exemplification of a constituent element, and does not limit a shape. Further, partial replacement or combination of configurations illustrated in different embodiments and variations is possible.

### REFERENCE NUMBERS

100, 100A to 100J: Stretchable device
10, 10A to 10J: Stretchable substrate
20, 20C to 20J: First stretchable wiring
21, 21C to 211: First electrode portion
22, 22C to 22G: First extending portion
30, 30C to 30J: Second stretchable wiring
31, 31C to 31I: Second electrode portion
32, 32C to 32H: Second extending portion
40, 40D to 40G, 40I, 40J: Interlayer sheet
40a, 40b: Substrate
41, 41D to 41J: Sheet portion
41DI to 41FI: Edge portion of interlayer sheet
42, 42D to 421: First via portion
43, 43D to 43I: Connection region
44, 44D to 44F: Non-connection region
45: Via portion
45a, 45b: Via hole
46: Second via portion
47: Third via portion
48: Conductive material
50G, 50H: Third stretchable wiring
51G, 51H: Electrode portion of third stretchable wiring
60G, 60H, 60J: Protective layer
70J, 80J: Internal stretchable wiring
71J: Electrode portion of internal stretchable wiring
72J: Extending portion of internal stretchable wiring

1. A stretchable device comprising:
a stretchable substrate;
a first stretchable wiring on the stretchable substrate and having a first electrode portion;
a second stretchable wiring on the first stretchable wiring and having a second electrode portion; and
an interlayer sheet between the first stretchable wiring and the second stretchable wiring, wherein
the interlayer sheet includes a sheet portion and at least one first via portion in the sheet portion, and
the first via portion has in a part thereof a connection region connecting the first electrode portion and the second electrode portion.

2. The stretchable device according to claim 1, wherein the second electrode portion overlaps a part of the first via portion in a plan view of the stretchable device.

3. The stretchable device according to claim 1, wherein the first via portion further includes a non-connection region that does not connect the first electrode portion and the second electrode portion.

4. The stretchable device according to claim 3, wherein the non-connection region of the first via portion is located outside of the second electrode portion in a plan view of the stretchable substrate.

5. The stretchable device according to claim 1, wherein the connection region occupies a part of the first via portion in a plan view of the stretchable substrate.

6. The stretchable device according to claim 1, wherein the interlayer sheet further has at least one second via portion overlapping a whole of the second electrode portion in a plan view of the stretchable substrate.

7. The stretchable device according to claim 6, wherein the second via portion includes the connection region.

8. The stretchable device according to claim 1, wherein the interlayer sheet further includes a third via portion that does not overlap the second electrode portion in a plan view of the stretchable substrate.

9. The stretchable device according to claim 6, wherein the interlayer sheet has a plurality of via portions regularly arranged at a predetermined interval in the sheet portion, and the plurality of via portions include the first via portion and the second via portion.

10. The stretchable device according to claim 9, wherein the plurality of via portions are arranged in a matrix.

11. The stretchable device according to claim 9, wherein a diameter of the plurality of via portions is smaller than a diameter of each of the first electrode portion and the second electrode portion.

12. The stretchable device according to claim 8, wherein the third via portion is a via hole or a via portion having a conductive material therein.

13. The stretchable device according to claim 3, wherein the non-connection region of the first via portion extends from the second electrode portion toward an edge portion of the interlayer sheet in a plan view of the stretchable substrate.

14. The stretchable device according to claim 13, wherein the non-connection region of the first via portion is continuous from the second electrode portion to an edge portion of the interlayer sheet in the plan view of the stretchable substrate.

15. The stretchable device according to claim 13, wherein the edge portion of the interlayer sheet is further inside than an edge portion of the stretchable substrate in the plan view of the stretchable substrate.

16. The stretchable device according to claim 1, further comprising a third stretchable wiring, wherein the first, second and third stretchable wirings are arranged in a thickness direction of the stretchable substrate, and an electrode portion of one of the first, second and third stretchable wirings that are adjacent to each other and an electrode portion of another one of the first, second and third stretchable wirings are mutually connected through the first via portion of the interlayer sheet.

17. The stretchable device according to claim 16, wherein the non-connection regions of two or more of the first via portions among the first, second and third stretchable wirings are arranged shifted in a plan view of the stretchable substrate.

18. The stretchable device according to claim 16, further comprising a fourth stretchable wiring that is not in contact with the first via portion.

19. The stretchable device according to claim 16, wherein among the first, second and third stretchable wirings, a stretchable wiring having a small region area is arranged between two stretchable wirings having a large region area in a thickness direction of the stretchable substrate.

20. The stretchable device according to claim 18, wherein among the first, second, third and fourth stretchable wirings, stretchable wirings having a small region area are arranged in parallel at a predetermined interval on the interlayer sheet.
